(19) United States
(12) Patent Application Publication
(10) Pub. No.: US 2008/0122092 A1
(43) Pub. Date: May 29, 2008

(54) Semiconductor Device and Method of Manufacturing the Same

(76) Inventor: JI HO HONG, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/932,256

(22) Filed: Oct. 31, 2007

(30) Foreign Application Priority Data
Nov. 29, 2006 (KR) 10-2006-0118808

(51) Int. Cl. H01L 23/52; H01L 21/4763

(52) U.S. Cl. 257/751; 438/643; 257/E23.141; 257/E21.495

(57) ABSTRACT

A semiconductor device and a fabricating method thereof are provided. An interlayer dielectric layer on a semiconductor substrate can have a via hole and can also have a trench over the via hole. A barrier layer can be provided on the interlayer dielectric layer having the via hole, a metal line can be provided in the via hole, and a protective layer for inhibiting corrosion of the metal line can be provided on the metal line.

### CROSS-REFERENCE TO RELATED APPLICATION

The present application claims the benefit under 35 U.S.C. §119 of Korean Patent Application No. 10-2006-0118808, filed Nov. 29, 2006, which is hereby incorporated by reference in its entirety.

### BACKGROUND

Semiconductor devices often have a multi-layer structure to allow for high-integration. Generally, a line including metal is formed to electrically connect between interlayer dielectric layers, such as pre-metallic dielectric (PMD) layers or inter-metallic dielectric (IMD) layers.

Aluminum (Al) or copper (Cu) is typically used as the metal in the line to connect interlayer dielectric layers.

Since copper can be susceptible to corrosion, the surface of a line can become corroded if formed of copper, such that copper particles become separated from the surface of the line. The copper particles can attach to a peripheral region, for instance, to the interlayer dielectric layer, leading to defects such as short circuits.

It is generally known in the art that it is difficult to pattern copper. Accordingly, copper is generally formed on an interlayer dielectric layer having a pattern which is already formed, such as a trench. A chemical mechanical polishing (CMP) process is then performed on the copper to form a metal line in the trench.

Corrosion of the copper often occurs mostly during the CMP process. When a line is formed using copper according to the related art, corrosion of copper is activated in the CMP process causing defects such as short circuits to occur more frequently.

Thus, there exists a need in the art for an improved semiconductor device and fabricating method thereof.

### BRIEF SUMMARY

Embodiments of the present invention provide a semiconductor device and a manufacturing method thereof in which a chemical mechanical polishing process is not performed. Corrosion of copper can be minimized, thereby improving the reliability of lines in the semiconductor device.

Also, a protective layer can be formed on copper to inhibit the copper from being corroded and to further improve the reliability of lines in the semiconductor device.

In an embodiment, a semiconductor device can include an interlayer dielectric layer on a semiconductor substrate and having a via hole (and wherein the interlayer dielectric layer can also have a trench over the via hole). A barrier layer can be provided on the interlayer dielectric layer having the via hole, and a metal line can be provided in the via hole. A protective layer can be provided on the metal line.

In another embodiment, a method of manufacturing a semiconductor device can include: forming an interlayer dielectric layer having a via hole on a semiconductor substrate; forming a barrier layer on the interlayer dielectric layer having the via hole; forming a first metal material on the barrier layer by using a first electro-chemical plating process; deplating a portion of the first metal material by using a second electro-chemical plating process so as to form a metal line in the via hole; depositing a second metal material on the barrier layer and on the metal line to form a protective layer on the metal line; and removing portions of the barrier layer and the second metal material that are not in the via hole.

In a further embodiment, a method of manufacturing a semiconductor device can include: forming an interlayer dielectric layer having a via hole and a trench on a semiconductor substrate; forming a barrier layer on the interlayer dielectric layer having the via hole and the trench; forming a first metal material on the barrier layer by using a first electro-chemical plating process; deplating a portion of the first metal material by using a second electro-chemical plating process so as to form a metal line in the via hole and the trench; forming a second metal material on the barrier layer and on the metal line to form a protective layer on the metal line; and removing portions of the barrier layer and the second metal material that are not in the trench or via hole.

### BRIEF DESCRIPTION OF THE DRAWINGS

FIG. 1 is a cross-sectional view showing a semiconductor device according to an embodiment of the present invention.

FIGS. 2A to 2G are cross-sectional views illustrating a method of manufacturing a semiconductor device according to an embodiment of the present invention.

FIG. 3 is a cross-sectional view showing a semiconductor device according to an embodiment of the present invention.

FIGS. 4A to 4G are cross-sectional views illustrating a method of manufacturing a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

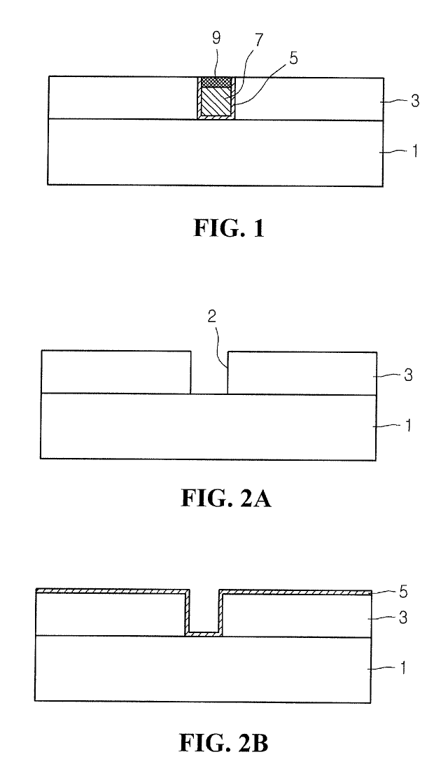

Referring to FIG. 1, a device module (not shown) having a predetermined function can be provided on a semiconductor substrate 1. The device module can be, for example, a memory or a logic circuit.

In an embodiment, an interlayer dielectric layer 3 having a via hole can be provided on the semiconductor substrate 1. In this embodiment, the interlayer dielectric layer 3 having a via hole is a single damascene structure. A barrier layer 5 for inhibiting copper from diffusing can be provided on the interlayer dielectric layer 3 including the via hole.

A copper metal line 7 can be provided on the barrier layer 5 in the via hole. In an embodiment, the upper surface of the copper metal line 7 can be lower than that of the barrier layer 5 provided on the interlayer dielectric layer 3, thereby forming a recess region.

A protective layer 9 can be provided on the copper metal line 7 in the recess region to inhibit copper from being corroded. The protective layer 9 can include, for example, aluminum. The surface of the aluminum can be changed into aluminum oxide (Al₂O₃) by reacting with oxygen in the atmosphere, and the aluminum oxide (Al₂O₃) can help inhibit copper from being corroded. In an embodiment, the protective layer 9 can include any suitable conductive material known in the art that inhibits corrosion of copper. The upper surface of the protective layer 9 can be even with or higher than that of the interlayer dielectric layer 3.

In an embodiment, the protective layer 9 can be provided on the copper metal line 7 in a single damascene structure.

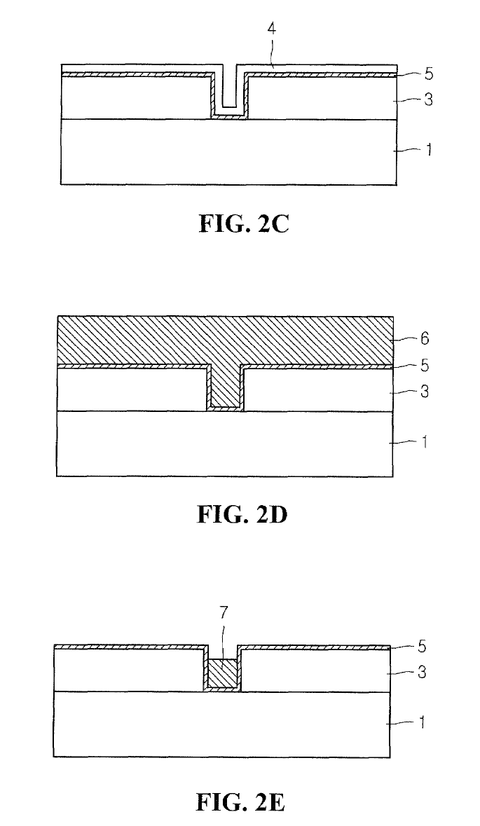

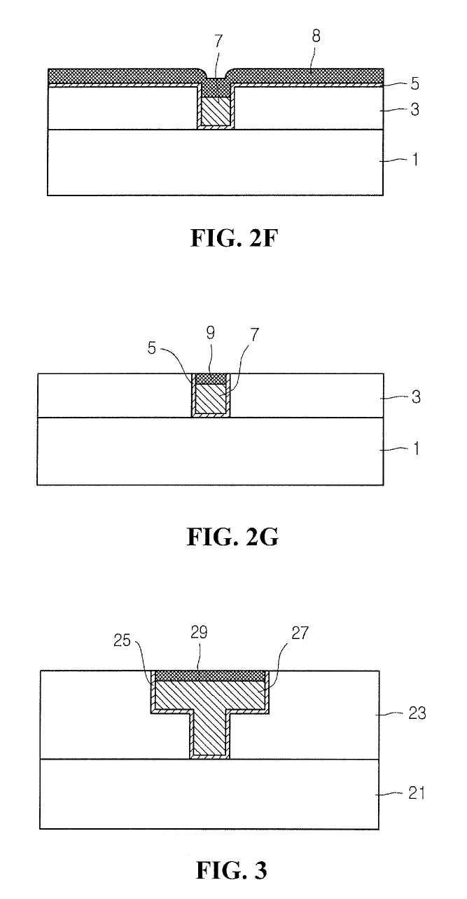

FIGS. 2A to 2G are cross-sectional views illustrating a method of manufacturing a semiconductor device according to an embodiment.

Referring to FIG. 2A, an interlayer dielectric layer 3 can be formed on a semiconductor substrate 1 having a device module. The interlayer dielectric layer 3 can be formed of, for example, undoped silicate glass (USG), boron-phosphorous doped silicate glass (BPSG), fluorine-doped silicate glass (FSG), or tetraethyl orthosilicate (TEOS).

A via hole 2 can be formed in the interlayer dielectric layer 3. The via hole 2 can be formed through any suitable process known in the art, for example, a dry etching process such as a reactive ion etching (RIE) process. In an embodiment, a plurality of via holes 2 can be provided corresponding to the number of device modules or signal paths.

Referring to FIG. 2B, a barrier layer 5 can be formed on the interlayer dielectric layer 3 including the via hole 2. The barrier layer 5 can be formed of TaN or any other suitable material known in the art. The barrier layer 5 can be used to inhibit copper from diffusing.

Referring to FIG. 2C, a seed layer 4 can be formed on the barrier layer 5. The seed layer 4 can be formed, for example, through a sputtering process. In one embodiment, the seed layer 4 can include copper. The seed layer 4 can serve to help form a copper metal line (see 7 in FIG. 2E) more easily.

Referring to FIG. 2D, copper material 6 can be deposited on the seed layer 4. The copper material can be deposited, for example, through an electro-chemical plating (ECP) process. The seed layer 4, when including copper, can combine with the copper material 6.

In an ECP process, a predetermined voltage can be applied to cause an oxidation-reduction reaction to plate a metal material on a surface. For example, if a forward voltage is applied, the metal material can be formed on the surface. However, if a reverse voltage is applied, the metal material can be deplated from the surface.

Accordingly, in an embodiment, the copper material 6 can be deposited on the seed layer 4 by applying a forward voltage in an ECP process.

Referring to FIG. 2E, the copper material 6 on the seed layer 4 can then be deplated. In an embodiment, the copper material 6 can be deplated by using an electro-chemical plating (ECP) process. The copper material 6 can be deplated by applying a reverse voltage in the ECP process. The ECP process can be performed until the upper surface of the copper material 6 remaining in the via hole 2 is lower than that of the barrier layer 5 on the interlayer dielectric layer 3.

The remaining copper material 6 can form a copper metal line 7.

Referring to FIG. 2F, a protective material 8 can be deposited on the barrier layer 5 including the copper metal line 7. The protective material 8 can be formed through a physical vapor deposition (PVD) process, a chemical vapor deposition (CVD) process, an atomic layer deposition (ALD) process or any other suitable process known in the art. The protective material 8 can be any suitable material known in the art, for example, aluminum.

Referring to FIG. 2G, the protective material 8 can be etched such that the protective material 8 remains on the copper metal line 7 in the via hole 2. The remaining protective material 8 can form a protective layer 9. Additionally, the barrier layer 5 on the interlayer dielectric layer 3 and not in the via hole 2 can be removed by the etching process.

Any suitable etching process can be used, such as a wet etching process or a dry etching process as long as the protective material 8 is left remaining only on the copper metal line 7 in the via hole 2 without remaining on the interlayer dielectric layer 3.

Accordingly, in an embodiment, the protective layer 9 can be formed on the copper metal layer 9 to inhibit corrosion of copper and improve the reliability of the metal line.

In addition, according to embodiments of the present invention a chemical mechanical polishing (CMP) process is not needed during the formation of a metal line. Acceleration of the corrosion of copper can be inhibited, thereby improving the reliability of the metal line.

FIG. 3 is a cross-sectional view showing a semiconductor device according to an embodiment of the present invention.

Referring to FIG. 3, a device module (not shown) can be formed on a semiconductor substrate 21. The device module can be, for example, memory or a logic circuit.

An interlayer dielectric layer 23 can be provided on the semiconductor substrate 21. In an embodiment, the interlayer dielectric layer 23 can have a dual damascene structure in which a via hole and a trench over the via hole are provided. Compared to a single damascene structure, the dual damascene structure can simplify the manufacturing process and reduce the manufacturing cost of a semiconductor device. While each metal line may be formed on a single layer in a single damascene process, a dual damascene structure can include metal lines simultaneously formed on two layers. Accordingly, a metal line, which may be formed through two steps in the single damascene structure, can be formed in one step in the dual damascene structure. While a single damascene structure and a dual damascene structure are described by way of example, the semiconductor device can be formed using any suitable damascene structure known in the art.

A barrier layer 25 can be provided on the interlayer dielectric layer 23 including the via hole and the trench to inhibit diffusion of copper.

A copper metal line 27 can be provided on the barrier layer 25 in the via hole and the trench. In an embodiment, the upper surface of the copper metal line 27 can be lower than that of the barrier layer 25 on the interlayer dielectric layer 23, thereby forming a recess region.

A protective layer 29 for inhibiting copper from being corroded can be provided on copper metal line 27 in the recess region. The protective layer 29 can include, for example, aluminum. The surface of the aluminum can be changed into aluminum oxide (Al₂O₃) by reacting with oxygen in the atmosphere, and the aluminum oxide (Al₂O₃) can help inhibit copper from being corroded. The protective layer 29 can include any suitable conductive material known in the art that inhibits copper from being corroded. The upper surface of the protective layer 29 can be even with or higher than that of the interlayer dielectric layer 23.

In an embodiment, the protective layer 29 can be provided on the copper metal line 27 of a dual damascene structure.

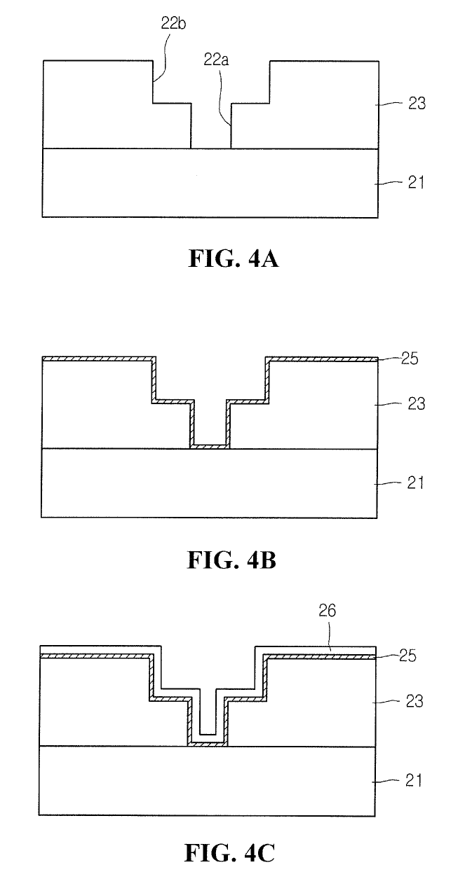

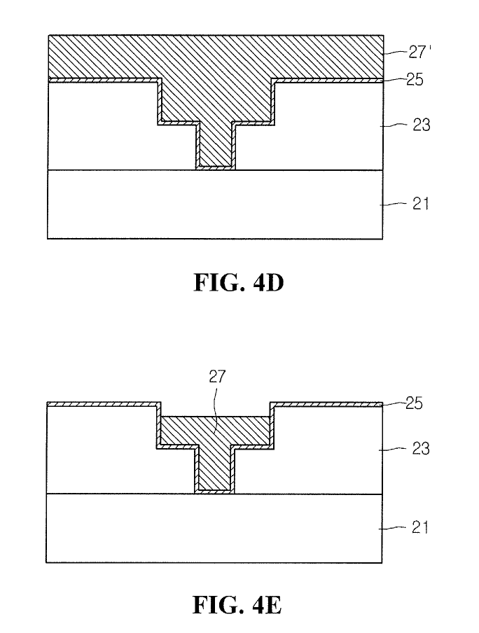

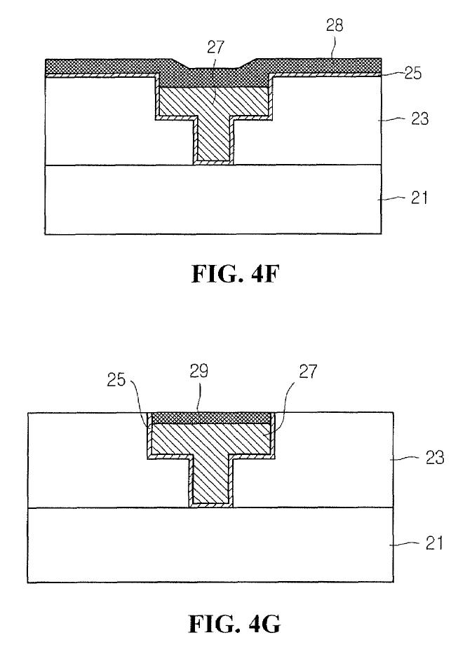

FIGS. 4A to 4G are cross-sectional views illustrating a method of manufacturing a semiconductor device according to an embodiment.

Referring to FIG. 4A, an interlayer dielectric layer 23 can be formed on a semiconductor substrate 21 having a device module. The interlayer dielectric layer 23 can be formed of, for example, USG, BPSG, FSG, or TEOS.

A via hole 22a and a trench 22b over the via hole 22a can be formed in the interlayer dielectric layer 23. The via hole 22a and the trench 22b can be formed through any suitable process known in the art, for example, a dry etching process such as a RIE process. In an embodiment, a plurality of via holes 22a and trenches 22b can be formed corresponding to the number of the device modules or signal paths.

Referring to FIG. 4B, a barrier layer 25 can be formed on the interlayer dielectric layer 23 including the via hole 22a and the trench 22b. The barrier layer 25 can be formed of TaN or any other suitable material known in the art. The barrier layer 25 can be used to inhibit diffusion of copper.

Referring to FIG. 4C, a seed layer 26 can be formed on the barrier layer 25. The seed layer 26 can be formed, for example, through a sputtering process. The seed layer 26 can include copper and can serve to help form a copper metal line (see 27 in FIG. 4E) more easily.

Referring to FIG. 4D, copper material 27′ can be deposited on the seed layer 26. The copper material 27′ can be deposited, for example, through an ECP process. The seed layer 26, when including copper, can combine with the copper material 27′.

In an ECP process, a predetermined voltage can be applied to cause an oxidation-reduction reaction to plate a metal material on a surface. For example, if a forward voltage is applied, the metal material can be formed on the surface. However, if a reverse voltage is applied, the metal material can be deplated from the surface.

Accordingly, in an embodiment, the copper material 27′ can be deposited on the seed layer 26 by applying a forward voltage in an ECP process.

Referring to FIG. 4E, the copper material 27′ on the seed layer 26 can then be deplated by using an ECP process. In an embodiment, the copper material 27′ can be depleted by applying a reverse voltage in the ECP process. The ECP process can be performed until the upper surface of the copper material 27′ remaining in the via hole 22a and trench 22b is lower than that of the barrier layer 25 on the interlayer dielectric layer 23.

The remaining copper material 27′ can form a copper metal line 27.

Referring FIG. 4F, a protective material 28 can be deposited on the barrier layer 25 including the copper metal line 27. The protective material 28 can be formed through a PVD process, a CVD process, an ALD process, or any other suitable process known in the art. The protective material 28 can be any suitable material known in the art, for example, aluminum.

Referring to FIG. 4G, the protective material 28 can be etched such that the protective material 28 remains on the copper metal line 27 in the via hole 22a and the trench 22b. The remaining protective material 28 can form a protective layer 29. Additionally, the barrier layer 25 on the interlayer dielectric layer 23 and not in the via hole 22a and trench 22b can be removed by the etching process.

Any suitable etching process known in the art can be used, such as a wet etching process or a dry etching process as long as the protective material 28 is left remaining only on the copper metal line 27 in the via hole 22a and the trench 22b without remaining on the interlayer dielectric layer 23.

Accordingly, in an embodiment, the protective layer 29 can be formed on the copper metal line 27 to inhibit corrosion of copper and improve the reliability of the line.

Also, according to embodiments of the present invention a chemical mechanical polishing (CMP) process is not needed during the formation of a metal line. Acceleration of the corrosion of copper can be inhibited, thereby improving the reliability of the metal line.

Furthermore, according to embodiments of the present invention, the protective layer can be formed to inhibit corrosion of the metal line, thereby improving the reliability of the line.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
an interlayer dielectric layer on a semiconductor substrate and having a via hole formed therein;
a barrier layer on the semiconductor substrate in the via hole;
a metal line on the barrier layer; and
a corrosion-inhibiting protective layer on the metal line.

2. The semiconductor device according to claim 1, wherein an upper surface of the metal line is lower than an upper surface of the interlayer dielectric layer.

3. The semiconductor device according to claim 1, wherein the metal line comprises copper.

4. The semiconductor device according to claim 1, wherein the protective layer comprises aluminum.

5. The semiconductor device according to claim 1, wherein an upper surface of the protective layer is even with or higher than an upper surface of the interlayer dielectric layer.

6. The semiconductor device according to claim 1, wherein the interlayer dielectric layer further comprises a trench over the via hole; wherein the barrier layer is also in the trench.

7. A method of manufacturing a semiconductor device, comprising:
forming an interlayer dielectric layer comprising a via hole on a semiconductor substrate;
forming a barrier layer on the interlayer dielectric layer comprising the via hole;
performing a first electro-chemical plating (ECP) process to form a first metal material on the barrier layer;
performing a second ECP process to deplate a portion of the first metal material to form a metal line in the via hole; and
depositing a second metal material on the barrier layer and the metal line to form a protective layer on the metal line.

8. The method according to claim 7, wherein performing the second ECP process comprises deplating the first metal material until an upper surface of the first metal material is lower than an upper surface of the interlayer dielectric layer.

9. The method according to claim 7, wherein performing the first ECP process comprises applying a forward voltage to the first metal material.

10. The method according to claim 7, wherein performing the second ECP process comprises applying a reverse voltage to the first metal material.

11. The method according to claim 7, wherein the first metal material comprises copper.

12. The method according to claim 7, wherein the second metal material comprises aluminum.

13. The method according to claim 7, further comprising removing a portion of the barrier layer and a portion of the second metal material from a top surface of the interlayer dielectric layer.

14. The method according to claim 13, wherein after removing a portion of the second metal material, an upper surface of the protective layer is even with or higher than an upper surface of the interlayer dielectric layer.

15. The method according to claim 13, wherein removing the portion of the barrier layer and the portion of the second metal material comprises performing a wet etching or dry etching process.

16. The method according to claim 7, wherein the interlayer dielectric layer further comprises a trench; and wherein the metal line is formed both in the via hole and the trench after performing the second ECP process.
